(19) United States
(12) Patent Application Publication
(10) Pub. No.: US 2012/0276749 A1
(43) Pub. Date: Nov. 1, 2012

(54) Method and Device for Treating Silicon Substrates

(75) Inventors: Dirk Habermann, Kirchzarten (DE); Martin Schoch, Freudenstadt (DE); Maher Izaaryene, Freudenstadt (DE); Friedhelm Stein, Lossburg (DE)

(73) Assignee: Gebr Schmid GmbH, Freudenstadt (DE)

(21) Appl. No.: 13/518,660

(22) PCT Filed: Dec. 23, 2010
(86) PCT No.: PCT/EP10/70651

§ 371 Date: Jul. 12, 2012

(30) Foreign Application Priority Data
Dec. 23, 2009 (DE) 10 2009 060 931.8

(51) Int. Cl. H01L 21/306; B05B 1/14

(52) U.S. Cl. 438/748; 156/345.21; 257/E21.219

(57) ABSTRACT

In a method for processing monocrystalline silicon wafers, which are transported while lying flat along a horizontal transport path, etching solution for texturing the surface is applied from above by means of nozzles or the like. The etching solution is applied from above several times in succession onto the upper side of the silicon substrates, remains there and reacts with the silicon substrate.

### APPLICATION FIELD AND PRIOR ART

The invention relates to a method for processing silicon substrates and to a device suitable therefor. In particular, it concerns the processing of monocrystalline silicon wafers, the upper side and advantageously also lower side of which is or are textured by means of etching solution.

From DE 102007063202 A1, it is known to spray silicon substrates continuously from above with etching solution. A mixture of HF and HNO₃ is used as the etching solution. Known texturing of the silicon substrate is carried out by the etching.

It is also known from DE 102008022282 to texture silicon substrates by etching. Here, gas bubbles formed on the surface of the silicon substrates are squeezed and removed by wide rollers bearing from above, so that as consistent as possible an etching result is achieved.

### OBJECT AND SOLUTION

It is an object of the invention to provide a method as mentioned in the introduction and a corresponding device for processing silicon substrates, with which problems of the prior art can be avoided, and in particular monocrystalline silicon wafers can also be processed or textured on their upper side, with the least possible outlay.

This object is achieved by a method having the features of Claim 1 and by a device having the features of Claim 9. Advantageous and preferred configurations of the invention are the subject-matter of the other claims, and will be explained in more detail below. Many of the features mentioned below are described only for the method or only for the device. Irrespective of this, however, they are intended to be applicable both for the method and for the device. The wording of the claims is incorporated into the content of the description by explicit reference.

The silicon substrates are transported while lying flat along a horizontal transport path, i.e. processed by an inline method. This offers advantages over previous methods, in which the silicon substrates have been held vertically. Etching solution for texturing the surface is applied or sprayed on at least from above, i.e. onto the upper side of the silicon substrates, which may be done by means of nozzles or spray nozzles or similar delivery devices. Etching solution is applied from above several times in succession, both chronologically in succession and, as seen in the throughput direction, onto the upper side of the silicon substrates. It remains on the upper side and reacts with the silicon substrate, i.e. etches it for texturing. A few micrometres of the silicon substrate may in this case be eroded. This creates the known pyramid shapes on the surface, which lead to better input i.e. less reflection of sunlight for a solar cell manufactured from the silicon substrate. By the repeated application of etching solution, the latter is respectively replaced or replenished, so that the etching process always takes place with fresh or refreshed etching solution.

Furthermore, an etching result which is as uniform as possible is thereby achieved.

For even further improvement of the etching process, according to the invention the etching solution contains an additive, which is selected from the group consisting of alcohol, surfactant, glycol and may comprise one or more thereof. The etching solution contains this additive in a small amount of at most a few wt %. By far the main effect of such an additive is that by reducing the surface tension of the etching solution, it is possible to reduce or even entirely avoid adhesion of gas bubbles from the reaction, which result from the silicon surface being processed with the etching solution. The gases resulting from the etching reaction, and the bubbles consequently formed, interfere with the etching process since they remain on the surface and shield the surface region covered by them, so that less or even no more etching takes place there.

A plurality of such wetting devices, formed for example as nozzles or spray nozzles or similar delivery devices, are provided successively in the throughput direction of the substrates through the device. They make it possible to coat the substrates at time intervals of from 1 to 300 sec on the surface, repeatedly with fresh chemicals.

Other possibilities are for the upper side, which is to be etched, to be processed with squeezing rollers according to DE 102008022282 A1 which so to speak squeeze off or squeeze away bubbles that have been formed, by linear contact on the upper side of the silicon substrates, and apply new etching solution to the upper side, or continuous strong spraying or flow application of etching solution, so as to remove the bubbles. In comparison with this, the method according to the invention has the advantage that it entails much less design or mechanical outlay and less undesired impairment of the silicon substrate surface. Owing to the small proportion of additive in the etching solution, the etching action is detrimentally affected only minimally or not at all. At the same time, this small proportion is already sufficient to reduce the surface tension in the etching solution to such an extent that precisely the said undesired bubbles do not remain adhering to the surface during the etching process.

In a refinement of the invention, the etching solution may additionally be redosed with the additive. In particular, this may be done chronologically speaking shortly before the etching solution is applied onto the silicon substrate. Conventionally, the etching solution is collected in a type of large storage tank or container, and for example a collecting trough, from which it is taken for application onto the silicon substrate. If the additive is already introduced here, in particular a highly volatile or readily evaporating additive such as alcohol, then it may vaporize. On the one hand, it will then no longer be present in the etching solution. On the other hand, it represents an environmental problem and may both attack the device or system and affect operating staff. Particularly advantageously, the additive is not added to the etching solution until the place where the etching solution is about to be applied onto the silicon substrate. In this regard, the additive may first be dosed into a wetting device, for example into an elongate tube or a similar container, which extends transversely over the transport path of the silicon substrates and is provided with nozzles or the like, through which wetting device the etching solution is delivered. Thus, for example, the etching solution may be connected via an addition opening for redosing to a connection of the wetting device to a supply line for the etching solution.

In another advantageous refinement of the invention, the etching solution may be continuously redosed with the additive. This thus applies to the etching solution delivered by means of the wetting device, so that the additive is respectively redosed according to the amount of etching solution delivered.

In one configuration of the invention, more and more additive may be added to the etching solution as the etching progresses, or in the throughput direction of the silicon substrates, for an ever greater proportion of additive in the etching solution. Thus, the proportion of additive in the etching solution may be increased greatly from the start of the etching to the end, for example even doubled.

The proportion of additive in the etching solution may advantageously be less than 1 wt %. Particularly advantageously, it may lie between 0.3 wt % and 0.6 wt %, and may for example be about 0.3 wt %. Even such a small proportion of additive has proven sufficient in practice to significantly reduce the bubble formation for an improved etching result.

In an advantageous configuration of the invention, an alkaline etching solution is used. It may comprise a small amount of KOH and/or NaOH, advantageously both together. This proportion is for example between 1 wt % and 10 wt %, advantageously somewhat more than 3 wt %. In this case, it has been found that particularly successful etching of the surface of the silicon substrates takes place.

In yet another configuration of the invention, it is possible to use heated etching solution for the silicon substrates. To this end, the etching solution may advantageously be heated or warmed before application onto the silicon substrates. This may be done either in an above-described stock of etching solution, and for example in a collection trough in the said system. As an alternative or in addition, a heater may be arranged directly in a wetting device for the etching solution, for example as a conventional electrically operated heating coil or tubular heating body, IR radiator, microwave heater, induction heater or the like. The etching solution may be heated to a few ° C. above room temperature, for example from 30° C. to 80° C., advantageously from 40° C. to 70° C.

In yet another configuration of the invention, it is possible to process or texture not only the upwardly facing upper side of the silicon substrates with the etching solution, but also the downwardly facing lower side. This may be done by spraying from below or by one or more wetting rollers, over which the silicon substrates travel or are transported. These wetting rollers are at least as wide as a silicon substrate, or even wider, and their surface is wetted with etching solution in order to transfer the etching solution onto the lower side of the silicon substrates. This is, however, fundamentally known from the prior art, see for example DE 102005062528 A1. The level of the etching solution in the tank may also be set at a level such that it just touches the substrates' surface to be processed.

These and other features are disclosed not only by the claims but also by the description and the drawings; the individual features may in each case be implemented individually or jointly in the form of subcombinations in an embodiment of the invention and in other fields, and may represent advantageous and per se protectable embodiments for which protection is claimed here. The subdivision of the application into individual sections and subheadings does not restrict the statements made therein in their general applicability.

### BRIEF DESCRIPTION OF THE DRAWINGS

An exemplary embodiment of the invention is schematically represented in the drawings and will be explained in more detail below. In the drawings,

FIG. 1 shows a view of a system according to the invention as seen in the throughput direction of the substrates, and

FIG. 2 shows a side view of a part of the system in FIG. 1.

### DETAILED DESCRIPTION OF THE EXEMPLARY EMBODIMENTS

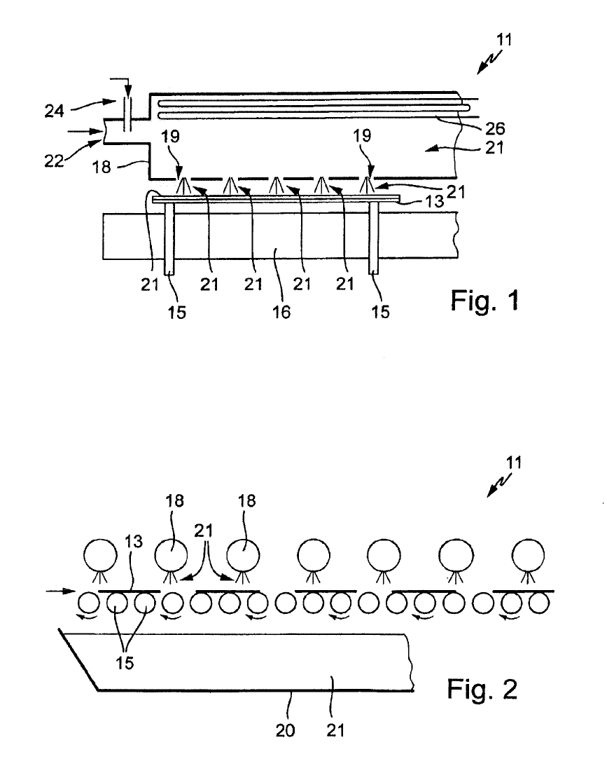

FIG. 1 represents a system 11 according to the invention as a device for processing silicon wafers 13 as silicon substrates, specifically in the throughput direction of these silicon wafers 13. They lie along a horizontal transport path, which is formed by transport rollers 15 on transport shafts 16. A plurality of silicon wafers 13 can be moved next to one another through the system 11, and, as shown by FIG. 2, a large number of them successively with a small spacing.

Above the transport path, a spray tube 18 is provided as a wetting device, which lies at a distance of a few centimetres from the upper side of the silicon wafers 13 and extends over the entire width of the transport path. A plurality of spray tubes 18 successively covers the transport path lengthwise. The spacing of the spray tubes 18 in FIG. 2 may for example be about 15 cm, but possibly somewhat more or somewhat less, or it may change over the length of the transport path.

The spray tube 18 comprises a plurality of spray nozzles 19 on its lower side, which may be formed as simple holes, openings or slits. The etching solution 21 can emerge through them and reach the surface of the silicon wafer 13, where it is distributed, as shown.

A redoser 24 is furthermore provided as a separate connection on the spray tube 18. Here, an additive as mentioned in the introduction, or a plurality thereof, can be redosed, or dosed, into the etching solution 21. This may be done a short time before the etching solution 21 is delivered from the spray tube 18, so that evaporation of the aforementioned highly volatile additives is kept at a very low level or can be entirely avoided. From FIG. 1 and FIG. 2 with the collecting trough 20 arranged below the transport rollers 15, it can in fact be seen clearly that after application of the etching solution 21 onto the upper side of the silicon wafers 13, where it forms a continuous layer, etching solution naturally also flows down or drips down therefrom. However, the highly volatile additive from the redoser 24, which may already be present beforehand in the etching solution 21 or may have been introduced therein, evaporates to a significant extent even before dripping off the silicon wafer 13, and only a small amount of it reaches the collecting trough 20 or the transport rollers 15. Thus, although the additive can still fulfill its function of reducing surface tension in the etching solution 21 on the silicon wafer 13, it cannot affect the overall system 11 so greatly. Volatile additives may be extracted through suction tubes, which are arranged between the rollers.

Besides isopropanol, the etching solution 21 may also contain other additives, advantageously a surfactant, in small amounts. This further reduces significantly the bubble formation when etching the surface of the wafer. By virtue of the redoser 24 for the additive, it is now in particular possible to supply precisely the amount of additive, or alcohol or isopropanol, which is directly necessary for the chemical reaction on the surface of the silicon wafer 13. The lower side of the silicon substrate may also be wetted and etching with the etching solution 21. To this end the transport rollers, for example as described in DE 102007063202 A1 or in DE 102005062528 A1, may additionally either be sprayed with etching solution 21 on the lower side, or owing to the transport rollers 15 extending over the entire width of the wafers they may also be wetted and etched on the lower side.

1. A method for processing silicon substrates, in particular monocrystalline silicon wafers, the method comprising the steps of:
transporting the silicon substrates while lying flat along a horizontal transport path; and
applying or spraying etching solution from above several times in succession from nozzles or the like onto an upper side of the silicon substrates for texturing the surface of the silicon substrates, wherein the etching solution remains there and reacts with the silicon substrate, the etching solution containing an additive selected from the group consisting of alcohol, surfactant, glycol in a small amount of at most a few wt %.

2. The method according to claim 1, wherein the etching solution is additionally redosed with the additive, in particular a short time before application onto the silicon substrate.

3. The method according to claim 1, wherein the etching solution is continuously redosed with the additive.

4. The method according to claim 1, wherein more and more additive is added to the etching solution as the etching progresses, or in the throughput direction, for an ever greater proportion of additive.

5. The method according to claim 4, wherein the proportion of additive is increased strongly towards the end of the transport path.

6. The method according to claim 1, wherein the etching solution is alkaline.

7. The method according to claim 1, wherein the etching solution is heated before application onto the silicon substrates.

8. The method according to claim 1, wherein the downwardly facing lower side of the silicon substrates is also wetted with the etching solution.

9. A device for processing silicon substrates in order to carry out the method according to claim 1, the device having a horizontal transport path for transporting silicon substrates through the device while they lie flat and for processing them while they lie flat, a plurality of wetting devices being arranged and extending over the width of the transport path, wherein the wetting devices comprise downwardly facing wetting openings and have a feed for etching solution, a redoser additionally being provided in the wetting device, in particular close to the wetting nozzles, in order to redose additive into the etching solution.

10. The device according to claim 9, wherein a heater for the wetting device or the etching solution is provided.

11. The device according to claim 9, wherein a wetting device is formed linearly and extends transversely over the transport path for the silicon substrates, the device comprising a plurality of these wetting devices.

12. The method according to claim 5, wherein the proportion of additive is doubled towards the end of the transport path

13. The method according to claim 6, wherein the etching solution comprises a small amount of KOH or NaOH.

14. The method according to claim 13, wherein the etching solution comprises between 1 wt % and 10 wt % of KOH or NaOH.

15. The method according to claim 7, wherein the etching solution is heated in a stock of etching solution or in a wetting device for the etching solution.

16. The method according to claim 8, wherein the downwardly facing lower side of the silicon substrates is wetted by spraying from below or by one or more wetting rollers, over which the silicon substrates travel or are transported.

17. The device according to claim 10, wherein the heater is provided in the wetting device itself or in an etching solution container.

18. The device according to claim 11, wherein the wetting device comprises a plurality of the wetting devices, arranged with a spacing of about 10 cm to 20 cm along the transport path.
